(19) United States
(12) Patent Application Publication
(10) Pub. No.: US 2024/0384058 A1
(43) Pub. Date: Nov. 21, 2024

(54) BLACK DISPERSION, ULTRAVIOLET-RAY-CURABLE BLACK COMPOSITION, RESIN COMPOSITION, BLACK MATRIX FOR COLOR FILTERS, AND CMOS CAMERA MODULE

(71) Applicants: MITSUBISHI MATERIALS CORPORATION, Tokyo (JP); Mitsubishi Materials Electronic Chemicals Co., Ltd., Akita-shi (JP)

(72) Inventors: Hiroto Akaike, Naka-shi (JP); Satoko Higano, Naka-shi (JP); Kensuke Kageyama, Akita-shi (JP); Naoyuki Aiba, Akita-shi (JP)

(73) Assignees: MITSUBISHI MATERIALS CORPORATION, Tokyo (JP); Mitsubishi Materials Electronic Chemicals Co., Ltd., Akita-shi (JP)

(21) Appl. No.: 18/684,703

(22) PCT Filed: Aug. 25, 2022
(86) PCT No.: PCT/JP2022/031985

§ 371 Date: Feb. 19, 2024

(30) Foreign Application Priority Data
Oct. 28, 2021 (JP) 2021-176295

(51) Int. Cl. C08K 3/28; G03F 7/00; H01L 27/146

(52) U.S. Cl. CPC C08K 3/28; G03F 7/0007; H01L 27/14623

(57) ABSTRACT

This black dispersion includes a solvent, a black pigment, and a polymer dispersant, in which the solvent contains either one or both of a monofunctional monomer having an ethylenically unsaturated bond and a difunctional monomer having an ethylenically unsaturated bond, the black pigment contains zirconium nitride, and the polymer dispersant contains a comb polymer, the comb polymer has a main chain and a plurality of side chains bonded to the main chain, the main chain is a polyalkyleneimine, and each of the plurality of side chains is a group containing an oxyethylene group and an oxypropylene group.

### DESCRIPTION

### Technical Field

The present invention relates to a black dispersion, an ultraviolet ray-curable black composition, a resin composition, a black matrix for color filters, and a CMOS camera module.

The present application claims priority on Japanese Patent Application No. 2021-176295 filed on Oct. 28, 2021, the content of which is incorporated herein by reference.

### Background Art

An insulating black pigment is used, for example, as a black matrix of a color filter for displays, a light shielding material in a CMOS camera module, and an optical adhesive. In addition, a dispersion containing a black pigment is used as a material for forming a black pattern such as a black resist or a black ink for inkjet. An ultraviolet ray-curable black composition including an insulating black pigment and an ultraviolet ray-curable organic substance has been known as the black resist.

An ultraviolet ray-curable black composition has been known which includes zirconium nitride particles as the insulating black pigment and an acrylic monomer or an epoxy monomer as the ultraviolet ray-curable organic substance. In addition, it is also known that a dispersant or a plasticizer is added to the ultraviolet ray-curable black composition. A polymer dispersant is known as the dispersant, and the polymer dispersant has a molecular weight of several thousand to tens of thousands and contains a secondary amine, a tertiary amine, a carboxylic acid, a phosphoric acid, or a phosphoric acid ester as a functional group to be adsorbed to an insulating black pigment (Patent Document 1).

In the ultraviolet ray-curable black composition, it is preferable that the black pigment is uniformly dispersed. For this reason, the ultraviolet ray-curable black composition is generally produced by dispersing a black pigment in a dispersion medium to prepare a uniform black dispersion, and then mixing the black dispersion and an ultraviolet ray-curable organic substance. However, the degree of oxidation (degree of nitridation) of the particle surface of the zirconium nitride particles used as the insulating black pigment may change depending on moisture or the atmosphere. Therefore, in a case where the black dispersion in which the zirconium nitride particles are dispersed is stored in the atmosphere for a long period of time, the surface of the zirconium nitride particles changes; and thereby, the affinity between the zirconium nitride particles and the dispersant is reduced; and as a result, the zirconium nitride particles are separated from the dispersant and the zirconium nitride particles may aggregate.

### CITATION LIST

### Patent Document

### [Patent Document 1]

Japanese Unexamined Patent Application, First Publication No. 2021-38119

### SUMMARY OF INVENTION

### Technical Problem

The present invention has been made in view of the above-mentioned circumstances, and the present invention aims to provide: a black dispersion in which black particles do not easily agglomerate even in a case of being stored in the atmosphere for a long period of time; an ultraviolet ray-curable black composition including the black dispersion; and a resin composition obtained by curing the ultraviolet ray-curable black composition. The present invention also aims to provide a black matrix for color filters and a CMOS camera module, each using the ultraviolet ray-curable black composition.

### Solution to Problem

In order to achieve the foregoing objects, an aspect of the present invention has the following features.

[1] A black dispersion including a solvent, a black pigment, and a polymer dispersant, in which the solvent contains either one or both of a monofunctional monomer having an ethylenically unsaturated bond and a difunctional monomer having an ethylenically unsaturated bond, the black pigment contains zirconium nitride, and the polymer dispersant contains a comb polymer, the comb polymer has a main chain and a plurality of side chains bonded to the main chain, the main chain is a polyalkyleneimine, and each of the plurality of side chains is a group containing an oxyethylene group and an oxypropylene group.

According to the black dispersion having the above-described configuration, the main chain of the polymer dispersant is a polyalkyleneimine; and therefore, the polymer dispersant has an extremely high affinity with the zirconium nitride contained in the black pigment. Therefore, the black particles and the polymer dispersant are unlikely to separate from each other even in a case where the surface of the black particles dispersed in the solvent changes.

In addition, the polymer dispersant is a comb polymer and has a plurality of side chains which are groups containing an oxyethylene group and an oxypropylene group; and therefore, the polymer dispersant has a high affinity with a monofunctional monomer having an ethylenically unsaturated bond and a difunctional monomer having an ethylenically unsaturated bond, which are solvents. Therefore, according to the black dispersion having the above-described configuration, the black particles are stably dispersed in the solvent, and the black particles are unlikely to be agglomerated even in a case of being stored in the atmosphere for a long period of time.

[2] The black dispersion according to [1], in which the comb polymer is a polymer represented by General Formula (I).

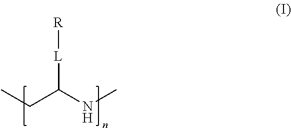

In General Formula (1), R represents a group containing an oxyethylene group and an oxypropylene group, L represents a single bond or a divalent linking group, and n represents a number of 5 to 30.

In this case, the main chain of the comb polymer is a polyethyleneimine and contains a large number of nitrogen atoms that have a high affinity with zirconium nitride; and therefore, the affinity between the comb polymer and the zirconium nitride becomes higher. Therefore, the black particles and the polymer dispersant are less likely to be separated, the black particles are more stably dispersed in the solvent, and the black particles are less likely to agglomerate.

[2a] The black dispersion according to [1] or [2], in which the solvent further contains an organic substance having no ethylenically unsaturated bond.

In this case, it becomes possible to adjust physical properties of the black dispersion such as viscosity and surface tension using an organic substance having no ethylenically unsaturated bond; and therefore, the range of application of the black dispersion can be expanded.

[3] An ultraviolet ray-curable black composition including the black dispersion according to [1], [2], or [2a], an ultraviolet ray-curable organic substance, and an ultraviolet curing agent.

According to the ultraviolet ray-curable black composition having the above-described configuration, the composition includes the above-described black dispersion; and therefore, the black particles are stably dispersed, and the black particles are unlikely to be agglomerated even in a case of being stored in the atmosphere for a long period of time. In addition, since an ultraviolet ray-curable organic substance and an ultraviolet curing agent are included, the composition can be cured by irradiation with ultraviolet rays.

Further, since the monofunctional monomer and the difunctional monomer contained as the solvent have an ethylenically unsaturated bond, when the ultraviolet ray-curable black composition is cured, the monofunctional monomer and the difunctional monomer are incorporated into the cured product of the ultraviolet ray-curable organic substance. As a result, a drying step after curing can be omitted or simplified.

[4] The ultraviolet ray-curable black composition according to [3], in which the ultraviolet ray-curable organic substance is an oligomer having an ethylenically unsaturated bond or a polyfunctional monomer having three or more ethylenically unsaturated bonds.

In this case, since the ultraviolet ray-curable organic substance is an oligomer or a polyfunctional monomer, the ultraviolet ray-curable black composition can be easily cured by irradiation with ultraviolet rays.

[5] The ultraviolet ray-curable black composition according to [3] or [4], in which the ultraviolet ray-curable black composition is used for a black resist.

In this case, since the black particles in the ultraviolet ray-curable black composition are stably dispersed, a uniform black pattern can be formed.

[6] A resin composition that is a cured product of the ultraviolet ray-curable black composition according to [3] or [4].

The resin composition having the above-described configuration is a cured product of the above-described ultraviolet ray-curable black composition; and therefore, the black particles are less likely to form secondary particles (agglomerated particles) and the black particles are uniformly dispersed. For this reason, the resin composition having the above-described configuration has uniform light shielding properties with respect to visible light.

[7] A black matrix for color filters including a cured product of the ultraviolet ray-curable black composition according to [3] or [4].

The black matrix for color filters having the above-described configuration includes a cured product of the above-described ultraviolet ray-curable black composition; and therefore, light shielding properties with respect to visible light is uniform. For this reason, a liquid crystal display or an organic EL display using the above-described black matrix for color filters has improved contrast of visible light.

[8] A CMOS camera module including a light shielding material containing a cured product of the ultraviolet ray-curable black composition according to [3] or [4].

The CMOS camera module having the above-described configuration includes a light shielding material containing a cured product of the above-described ultraviolet ray-curable black composition; and therefore, light shielding properties with respect to unnecessary visible light is improved. For this reason, a digital camera using the CMOS camera module having the above-described configuration has high sensitivity.

### Advantageous Effects of Invention

According to an aspect of the present invention, it is possible to provide: a black dispersion in which black particles do not easily agglomerate even in a case of being stored in the atmosphere for a long period of time; an ultraviolet ray-curable black composition including the black dispersion; and a resin composition obtained by curing the ultraviolet ray-curable black composition.

### DESCRIPTION OF EMBODIMENTS

Hereinafter, a black dispersion, an ultraviolet ray-curable black composition, a resin composition, a black matrix for color filters, and a CMOS camera module according to an embodiment of the present invention will be described.

### [Black Dispersion]

The black dispersion of the present embodiment includes a solvent, a black pigment, and a polymer dispersant.

The solvent contains either one or both of a monofunctional monomer having an ethylenically unsaturated bond and a difunctional monomer having an ethylenically unsaturated bond. For example, a (meth)acrylic monofunctional monomer having a (meth)acryloyl group, a (meth)acrylic difunctional monomer having a (meth)acryloyl group, and a vinyl-based monofunctional monomer having a vinyl group can be used as the monofunctional monomer having an ethylenically unsaturated bond and the difunctional monomer having an ethylenically unsaturated bond. Examples of the acrylic monofunctional monomer include (meth)acrylic acid, methyl (meth)acrylate, ethyl (meth)acrylate, propyl (meth)acrylate, n-butyl (meth)acrylate, isobutyl (meth)acrylate, 2-ethylhexyl (meth)acrylate, octyl (meth)acrylate, isooctyl (meth)acrylate, isodecyl (meth)acrylate, lauryl (meth)acrylate, stearyl (meth)acrylate, benzyl (meth)acrylate, phenyl (meth)acrylate, phenoxyethyl (meth)acrylate, 2-hydroxyethyl (meth)acrylate, 2-hydroxypropyl (meth)acrylate, isoamyl acrylate, tetrahydrofurfuryl (meth)acrylate, and isobornyl (meth)acrylate. Examples of the acrylic difunctional monomer include 1,6-hexanediol di(meth)acrylate, 1,9-nonanediol di(meth)acrylate, neopentyl glycol di(meth)acrylate, polyethylene glycol di(meth)acrylate, ethylene oxide-modified bisphenol A di(meth)acrylate, and neopentyltriethylene glycol di(meth)acrylate. Examples of the vinyl-based monofunctional monomer include vinyl chloride and vinyl acetate.

The amount of the monofunctional monomer having an ethylenically unsaturated bond and the difunctional monomer having an ethylenically unsaturated bond is preferably 10 parts by mass to 95 parts by mass with respect to 100 parts by mass of the black dispersion. In a case where the amount of the monofunctional monomer having an ethylenically unsaturated bond and the difunctional monomer having an ethylenically unsaturated bond is in this range, the black pigment can be easily dispersed and the storage stability is excellent. The amount of the monofunctional monomer having an ethylenically unsaturated bond and the difunctional monomer having an ethylenically unsaturated bond is more preferably in a range of 30 parts by mass or more and 95 parts by mass or less, and particularly preferably in a range of 50 parts by mass or more and 90 parts by mass or less.

An organic substance having no ethylenically unsaturated bond may be added as the solvent. Examples of the solvent having no ethylenically unsaturated bond include a glycol ethers such as ethyl carbitol, ethyl carbitol acetate, butyl carbitol acetate (BCA), butyl carbitol, methyl cellosolve, ethyl cellosolve, diethylene glycol ethyl methyl ether, propylene glycol monomethyl ether, propylene glycol monomethyl ether acetate (PGMEA), propylene glycol monoethyl ether, dipropylene glycol monomethyl ether, dipropylene glycol monoethyl ether, triethylene glycol monomethyl ether, triethylene glycol monoethyl ether, and the like, a-terpineol, methyl ethyl ketone (MEK), ethyl acetate, butyl acetate, n-propanol, isopropanol, methanol, ethanol, toluene, and the like.

In a case where a solvent having no ethylenically unsaturated bond is used, the amount thereof is preferably in a range of 1 part by mass or more and 60 parts by mass or less with respect to 100 parts by mass of the total amount of the monofunctional monomer having an ethylenically unsaturated bond and the difunctional monomer having an ethylenically unsaturated bond. In a case where the amount of the solvent having no ethylenically unsaturated bond is in this range, physical properties of the black dispersion such as viscosity and surface tension can be adjusted. The amount of the solvent having no ethylenically unsaturated bond is more preferably in a range of 5 parts by mass or more and 50 parts by mass or less, and particularly preferably in a range of 10 parts by mass or more and 40 parts by mass or less.

The black pigment is dispersed as black particles in the solvent. The black pigment contains zirconium nitride. The black particles contained in the black pigment preferably contain 80% by mass or more of zirconium nitride, and more preferably 90% by mass or more of zirconium nitride. The black particles may be zirconium nitride particles. The zirconium nitride particles may contain oxygen. In addition, the zirconium nitride particles may contain a metal element other than zirconium.

The average particle diameter of the black pigment may be 500 nm or less. The average particle diameter of the black pigment is more preferably in a range of 10 nm or more and 400 nm or less, and particularly preferably in a range of 10 nm or more and 300 nm or less. The average particle diameter of the black pigment is a BET diameter calculated in accordance with Expression (1) assuming that the particle shape is spherical, from a BET specific surface area measured by the BET method and a density. In Expression (1), L represents an average particle diameter (m) of the black pigment, ρ represents a true density (g/m³) of the black pigment and S represents a specific surface area value (m²/g) of the black pigment. The BET specific surface area can be measured, for example, using a specific surface area measuring device (SA-1100, manufactured by Sibata Scientific Technology Ltd.) by a single-point BET method using nitrogen adsorption.

$$L = 6 / ( ρ \times S ) \qquad ( 1 )$$

The black pigment can be produced, for example, by using a method in which a zirconium oxide powder is reacted with a nitrogen gas in the presence of a reduction catalyst to reduce the zirconium oxide powder (thermite method). For example, a metal magnesium powder can be used as the reduction catalyst. A magnesium oxide powder may be added to the metal magnesium powder. The zirconium nitride particles produced using metal magnesium as the reduction catalyst contain magnesium as inevitable impurities. The amount of magnesium in the zirconium nitride particles may be in a range of 0.1% by mass or more and 5.0% by mass or less.

In addition, the black pigment can be produced by a method for reducing metal zirconium particles or zirconium oxide particles in a nitrogen gas atmosphere using a plasma nanoparticle production device (plasma synthesis method). High-purity zirconium nitride particles can be obtained by using this plasma synthesis method.

The amount of the black pigment in the black dispersion is preferably in a range of 5% by mass or more and 50% by mass or less. In a case where the amount of the black pigment is in this range, the black pigment can be stably dispersed. The amount of the black pigment is more preferably in a range of 5% by mass or more and 45% by mass or less, and particularly preferably in a range of 10% by mass or more and 40% by mass or less.

The polymer dispersant contains a comb polymer having a main chain and a plurality of side chains bonded to the main chain. The main chain is a polyalkyleneimine. The polyalkyleneimine of the main chain consists of repeating units of an imino group and an alkylene group. The number of carbon atoms in the alkylene group may be in a range of 2 to 6. The polyalkyleneimine may be linear or branched.

The hydrogen atom of the imino group may be substituted with a terminal alkylamino group (—R¹NH₂:R¹ is an alkyl group having 2 to 6 carbon atoms), and the hydrogen atom of the amino group of the alkylamino group may be further substituted with an alkylamino group. The hydrogen atom of the alkyl group of the alkylamino group may be substituted with a group containing an oxyethylene group and an oxypropylene group. Each of the plurality of side chains is a group containing an oxyethylene group and an oxypropylene group. The number of oxyethylene groups contained in each side chain may be in a range of 1 to 20, and the number of oxypropylene groups contained in each side chain may be in a range of 1 to 20. A plurality of oxyethylene groups and a plurality of oxypropylene groups may each form a block copolymer. The main chain of the comb polymer is bonded to zirconium nitride contained in the black particles, and the side chain of the comb polymer is bonded to a monofunctional monomer having an ethylenically unsaturated bond contained in the solvent. In addition, the number average molecular weight (Mn) of the polymer dispersant determined by gel permeation chromatography (GPC) measurement may be in a range of 500 to 10000.

The comb polymer may be a polymer represented by General Formula (I).

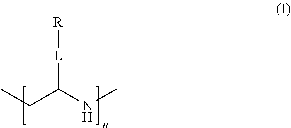

In General Formula (I), n represents a number of 5 to 30.

In General Formula (I), L represents a single bond or a divalent linking group. The divalent linking group is an oxygen atom (—O—), a carbonyl group (—CO—), an alkylene group having 1 to 8 carbon atoms, or a group obtained by combining two or more of these groups. The alkylene group may have a substituent or may not have a substituent. An example of the substituent is an alkyl group having 1 to 3 carbon atoms. A group obtained by combining an oxygen atom and an alkylene group, or a group obtained by combining an oxygen atom, a carbonyl group, and an alkylene group can be used as the group obtained by combining two or more types of groups. Examples of the group obtained by combining an oxygen atom and an alkylene group include ·¹—O-alkylene group-O—·² (·¹ represents a bonding site that is bonded to a carbon atom of polyalkyleneimine, and ·² represents a bonding site that is bonded to R). Examples of the group obtained by combining an oxygen atom, a carbonyl group, and an alkylene group include —·¹—O—CO-alkylene group-CO—O—·² (·¹ represents a bonding site that is bonded to a carbon atom of polyalkyleneimine, and ·² represents a bonding site that is bonded to R).

In General Formula (I), R is a group containing an oxyethylene group and an oxypropylene group. R may be a group represented by General Formula (II) or General Formula (III).

—(PO)ₚ-(EO)_{q}—X (II)

—(PO)ᵣ-(EO)ₛ—(PO)ₜ-(EO)ᵤ—X (III)

In General Formula (II) and General Formula (III), PO represents an oxypropylene group and EO represents an oxyethylene group. X represents a hydrogen atom or a methyl group. p and q in General Formula (II) each represent any number of 1 to 20. r, s, t, and u in General Formula (III) each represent any number of 1 to 10.

The amount of the polymer dispersant in the black dispersion is preferably in a range of 1 part by mass or more and 50 parts by mass or less with respect to 100 parts by mass of the black pigment. In a case where the amount of the polymer dispersant is in this range, the dispersibility of the black pigment can be improved. The amount of the polymer dispersant is more preferably in a range of 2 parts by mass or more and 45 parts by mass or less, and particularly preferably in a range of 5 parts by mass or more and 40 parts by mass or less.

The black dispersion may include other additives. Examples of other additives include rheology controlling agents such as a surfactant, a plasticizer, and a leveling agent, and a plurality of these additives may be used in combination. In addition, the black dispersion may include a polymerization inhibitor in order to suppress the polymerization of the monofunctional monomer and the difunctional monomer.

The black dispersion can be produced, for example, by mixing a solvent, a black pigment, and a polymer dispersant, and subjecting the obtained mixture to a dispersion treatment. A bead mill, an ultrasonic disperser, or the like can be used as the dispersion treatment device.

According to the black dispersion of the present embodiment configured as described above, since the main chain of the polymer dispersant is a polyalkyleneimine, the polymer dispersant has an extremely high affinity with zirconium nitride contained in the black pigment. Therefore, the black particles and the polymer dispersant are unlikely to separate from each other even in a case where the surface of the black particles dispersed in the solvent changes. In addition, the polymer dispersant is a comb polymer and has a plurality of side chains which are groups containing an oxyethylene group and an oxypropylene group; and therefore, the polymer dispersant has a high affinity with a monofunctional monomer having one ethylenically unsaturated bond and a difunctional monomer having two ethylenically unsaturated bonds, which are solvents. Therefore, according to the black dispersion of the present embodiment, the black particles are stably dispersed in the solvent, and the black particles are unlikely to be agglomerated even in a case of being stored in the atmosphere for a long period of time.

In addition, in a case where the black dispersion of the present embodiment has a configuration in which the comb polymer is a polymer represented by General Formula (I), the main chain of the comb polymer is a polyethyleneimine and contains a large number of nitrogen atoms that have a high affinity with zirconium nitride; and therefore, the affinity between the comb polymer and the black particles becomes higher. Therefore, the black particles and the polymer dispersant are less likely to be separated, the black particles are more stably dispersed in the solvent, and the black particles are less likely to agglomerate.

In addition, in the black dispersion of the present embodiment, an organic substance having no ethylenically unsaturated bond may be further added as a solvent to adjust physical properties of the black dispersion, such as viscosity and surface tension. Accordingly, the range of application of the black dispersion can be expanded.

### [Ultraviolet Ray-Curable Black Composition]

The ultraviolet ray-curable black composition of the present embodiment includes the above-described black dispersion, an ultraviolet ray-curable organic substance, and an ultraviolet curing agent. That is, the ultraviolet ray-curable black composition includes a solvent, a black pigment, a polymer dispersant, an ultraviolet ray-curable organic substance, and an ultraviolet curing agent. The amount of the black pigment in the ultraviolet ray-curable black composition is, for example, in a range of 0.1% by mass or more and 60% by mass or less.

For example, an oligomer having an ethylenically unsaturated bond or a polyfunctional monomer having three or more ethylenically unsaturated bonds can be used as the ultraviolet ray-curable organic substance. The oligomer having an ethylenically unsaturated bond may be an acrylic oligomer having two or more (meth)acryloyl groups. The acrylic oligomer is a low molecular weight polymer obtained by polymerizing an acrylic monofunctional monomer. Examples of the acrylic oligomer include an acrylic (meth)acrylate, an urethane (meth)acrylate, an epoxy (meth)acrylate, and a polyester (meth)acrylate. The molecular weight of the acrylic oligomer may be, for example, in a range of 1000 or more and 10000 or less in terms of number average molecular weight. These (meth)acrylate monomers and oligomers can be used alone or in combination of two or more thereof. In addition, the acrylic oligomer is not limited to those listed above, and commonly available oligomers can be used. The polyfunctional monomer having an ethylenically unsaturated bond may be an acrylic polyfunctional monomer having three or more (meth)acryloyl groups. Examples of the acrylic polyfunctional monomer include pentaerythritol tri(meth)acrylate, pentaerythritol tetra (meth)acrylate, and trimethylolpropane tri(meth)acrylate.

The amount of the ultraviolet ray-curable organic substance is, for example, in a range of 5 parts by mass or more and 99 parts by mass or less with respect to 100 parts by mass of the ultraviolet ray-curable black composition.

The ultraviolet ray-curable black composition may include another ultraviolet ray-curable organic substance. Examples of the other ultraviolet ray-curable organic substance include a styrene-based monomer and a cationic polymerizable monomer. Examples of the styrene-based monomer include styrene, vinyltoluene, and divinylbenzene. Examples of the cationic polymerizable monomer include oxetane.

The ultraviolet curing agent is preferably a compound capable of absorbing ultraviolet rays, specifically light having a wavelength of 100 to 400 nm to initiate a polymerization reaction. The ultraviolet curing agent may be, for example, a radical generator or a photoacid generator. Examples of the ultraviolet curing agent include an acetophenone-based compound, a benzophenone-based compound, a benzoin ether-based compound, a triazine compound, a phosphine oxide-based compound, a sulfonium-based compound, and an organic peroxide. Examples of the acetophenone-based compound include acetophenone, dimethylacetophenone, and 2-hydroxy-2-methylpropiophenone. Examples of the benzophenone-based compound include benzophenone and 2-chlorobenzophenone. Examples of the benzoin ether-based compound include benzoin and benzoin methyl ether. Examples of the phosphine oxide-based compound include bis(2,4,6-trimethylbenzoyl)phenylphosphine oxide and 2,4,6-trimethylbenzoyl-diphenylphosphine oxide. Examples of the sulfonium-based compound include bis(4-tert-butylphenyl)iodonium hexafluorophosphate, triphenylsulfonium tetrafluoroborate, and tri-p-tolylsulfonium trifluoromethanesulfonate. Examples of the organic peroxide include benzoyl peroxide and cumene peroxide.

The amount of the ultraviolet curing agent is, for example, in a range of 0.5 parts by mass or more and 15 parts by mass or less with respect to 100 parts by mass of the ultraviolet ray-curable organic substance.

The ultraviolet ray-curable black composition may include a plasticizer. Examples of the plasticizer include a phosphoric acid ester-based plasticizer, a phthalic acid ester-based plasticizer, an aliphatic-basic acid ester-based plasticizer, an aliphatic dibasic acid ester-based plasticizer, a divalent alcohol ester-based plasticizer, and an oxy acid ester-based plasticizer. Examples of the phosphoric acid ester-based plasticizer include tributyl phosphate and 2-ethylhexyl phosphate. Examples of the phthalic acid ester-based plasticizer include dimethyl phthalate and dibutyl phthalate. Examples of the aliphatic-basic acid ester-based plasticizer include butyl oleate and glycerin monooleate. Examples of the aliphatic dibasic acid ester-based plasticizer include dibutyl adipate and di(2-ethylhexyl)sebacate. Examples of the divalent alcohol ester-based plasticizer include diethylene glycol dibenzoate and triethylene glycol di-(2-ethyl butyrate). Examples of the oxy acid ester-based plasticizer include methyl acetyl ricinoleate and tributyl acetyl citrate.

In a case where a plasticizer is used, the amount thereof is, for example, in a range of 1 part by mass or more and 100 parts by mass or less with respect to 100 parts by mass of the ultraviolet ray-curable organic substance.

The ultraviolet ray-curable black composition may include a polymerization inhibitor in order to improve the storage stability. Examples of the polymerization inhibitor include: a phenol derivative such as hydroquinone, hydroquinone monomethyl ether, t-butylphenol, and the like; a benzoquinone derivative such as benzoquinone, 2-methyl-1,4-benzoquinone, and the like; a nitro compound such as dinitrobenzene, nitrophenol, and the like; a nitroso compound such as nitrosobenzene, phenothiazine, phenyl-t-butyl nitrone, and the like; iron (III) chloride, sulfur, and the like. One of these polymerization inhibitors may be used alone or two or more thereof may be used in combination.

In a case where a polymerization inhibitor is used, the amount thereof may be in a range that does not inhibit curing of the ultraviolet ray-curable black composition when the ultraviolet ray-curable black composition is cured by irradiation with ultraviolet rays and is, for example, in a range of 5.0×10⁻⁴ parts by mass or more and 5.0×10⁻² parts by mass or less with respect to 100 parts by mass of the ultraviolet ray-curable organic substance.

The ultraviolet ray-curable black composition may include other additives. Examples of other additives include rheology controlling agents such as a surfactant and a leveling agent, and a plurality of types of these additives may be used in combination.

The ultraviolet ray-curable black composition can be produced, for example, by mixing the black dispersion, the ultraviolet ray-curable organic substance, and the ultraviolet curing agent. The mixing method is not particularly limited, and mixing can be carried out using, for example, a mixing device such as a planetary stirrer, a bead mill, or a three-roll mill.

According to the ultraviolet ray-curable black composition of the present embodiment configured as described above, since the composition includes the above-described black dispersion, the black particles are stably dispersed, and the black particles are unlikely to be agglomerated even in a case of being stored in the atmosphere for a long period of time. In addition, since the ultraviolet ray-curable black composition of the present embodiment includes an ultraviolet ray-curable organic substance and an ultraviolet curing agent, the composition can be cured by irradiation with ultraviolet rays. In addition, in a case where the ultraviolet ray-curable black composition of the present embodiment has a configuration in which the ultraviolet ray-curable organic substance is an oligomer having an ethylenically unsaturated bond or a polyfunctional monomer having three or more ethylenically unsaturated bonds, the composition can be easily cured by irradiation with ultraviolet rays. In addition, since the black particles are stably dispersed in the ultraviolet ray-curable black composition of the present embodiment, a uniform black pattern can be formed by using the ultraviolet ray-curable black composition of the present embodiment as a black resist.

### [Resin Composition]

The resin composition of the present embodiment is a cured product of the above-described curable black composition. For example, the resin composition is formed as follows. A coated film is formed by applying the curable black composition onto a base plate. In a case where the curable black composition includes a solvent that does not have ultraviolet curability, the solvent in the coated film is removed by volatilization. Next, the coated film is irradiated with ultraviolet rays to polymerize the ultraviolet ray-curable organic substance to generate a resin. A halogen lamp, a metal halide lamp, a UV-LED, or the like can be used as a light source of ultraviolet rays. The light source is not particularly limited as long as it has a wavelength that matches the absorption wavelength of the ultraviolet curing agent.

According to the resin composition of the present embodiment configured as described above, since the resin composition is a cured product of the above-described ultraviolet ray-curable black composition, the black particles are less likely to form agglomerated particles and the black particles are uniformly dispersed. For this reason, the resin composition of the present embodiment has uniform light shielding properties with respect to visible light. The resin composition of the present embodiment can be advantageously used as a black matrix for color filters, a black resist, or a light shielding material for a CMOS camera module.

The resin composition of the present embodiment has an optical density (OD) value of, for example, 2.5 or more and preferably 3.0 or more, and the optical density (OD) is one of the indexes representing the light shielding properties (attenuation of transmittance) of a resin. The upper limit of the OD value is, for example, 5.0 or less.

The OD value is a logarithmic representation of a degree to which light is absorbed when light passes through a black film, and is defined by Expression (2). In Expression (2), I is an amount of transmitted light and I₀ is an amount of incident light.

$$OD value = - {log}_{10} ( I / {I}_{0} ) \qquad ( 2 )$$

The better dispersibility of the black particles in the resin composition, the higher the OD value of the resin composition tends to be.

### [Black Matrix for Color Filters]

The black matrix for color filters of the present embodiment includes a cured product of the above-described ultraviolet ray-curable black composition. The black matrix for color filters can be used as a black matrix for a liquid crystal display or an organic EL display. Since the black matrix for color filters of the present embodiment includes a cured product of the above-described ultraviolet ray-curable black composition, light shielding properties with respect to visible light is uniform. For this reason, a liquid crystal display or an organic EL display using the black matrix for color filters of the present embodiment has improved contrast of visible light.

### [CMOS Camera Module]

The CMOS camera module of the present embodiment includes a light shielding material containing a cured product of the above-described ultraviolet ray-curable black composition. The CMOS camera module can be used as a solid-state imaging element of a digital camera. Since the CMOS camera module of the present embodiment includes a light shielding material containing a cured product of the above-described ultraviolet ray-curable black composition, light shielding properties with respect to unnecessary visible light become high. For this reason, a digital camera using the CMOS camera module of the present embodiment has high sensitivity.

Although the embodiments of the present invention have been described above, the present invention is not limited thereto, and modifications can be made as appropriate without departing from the technical features of the invention.

### EXAMPLES

In the example, the following dispersants A to F were used as polymer dispersants.

Dispersant A: a comb polymer whose main chain was a polyethyleneimine and whose side chain was a group having an oxyethylene group and an oxypropylene group (number average molecular weight: 3500)

Dispersant B: a comb polymer whose main chain (adsorptive functional group) was a polyethyleneimine and whose side chain was a group having an oxyethylene group and an oxypropylene group (number average molecular weight: 3000)

Dispersant C: a comb polymer whose main chain (adsorptive functional group) was a polyethyleneimine and whose side chain was a group having an oxyethylene group and an oxypropylene group (number average molecular weight: 4000)

Dispersant D: a phosphoric acid ester-based dispersant whose adsorptive functional group was a phosphoric acid group and whose structural formula was (C₂H₄O)ₙC₁₈H₃₆O₉(H₃O₄P)ₓ (n=1 to 10, and x=1 to 3) (number average molecular weight: 1000)

Dispersant E: a comb polymer whose main chain (adsorptive functional group) was a (poly) carboxylic acid and which had an unsaturated alkyl group bonded to a carboxylic acid (number average molecular weight: 1500)

Dispersant F: a phosphoric acid ester whose adsorptive functional group was a phosphoric acid group and which consisted of an oxyethylene group connected to a phosphoric acid and an oxypropylene group bonded to the oxyethylene group (number average molecular weight: 3000)

### Invention Example 1

7.4 parts by mass of a zirconium dioxide powder having an average primary particle diameter of 50 nm, 7.3 parts by mass of a metal magnesium powder having an average primary particle diameter of 150 μm, and 7.3 parts by mass of a magnesium oxide powder were placed in a mortar and mixed using a pestle to obtain a mixture. This mixture was sintered at a temperature of 700°° C. for 60 minutes in a nitrogen gas atmosphere using a reaction device equipped with a graphite boat inside a quartz glass tube to obtain a sintered product. This sintered product was dispersed in water at a concentration of 20 g/L, and a 10% aqueous hydrochloric acid solution was gradually added thereto so that the pH of the obtained dispersion did not become less than 1. Next, the dispersion was stirred while maintaining the liquid temperature not to exceed 100°° C. to wash the sintered product. Then, 25% aqueous ammonia was added to the dispersion to adjust the pH to 7 to 8. Subsequently, the dispersion was filtered to recover the nonvolatile content. The recovered nonvolatile content was re-dispersed in water at a concentration of 100 g/L, and again subjected to acid washing and pH adjustment with aqueous ammonia in the same manner as described above. Then the dispersion was filtered. In this manner, acid washing and pH adjustment with aqueous ammonia were repeated twice. Next, the filtered residue was dispersed in ion-exchanged water at a concentration of 500 g/L in terms of solid amount, heated and stirred at 60° C., and the pH thereof was adjusted to 7. Then, the resultant liquid was filtered by a suction filtration device, further washed with an equal amount of ion-exchanged water, and dried in a hot air dryer at a set temperature of 120°° C. to obtain a black pigment containing zirconium nitride. The obtained black pigment had an average particle diameter (BET diameter) of 30 nm.

20 parts by mass of the black pigment obtained above, 4 parts by mass of the above-mentioned dispersant A (20% by mass as amount with respect to the black pigment), and benzyl acrylate as the solvent in an amount such that a total amount of all components was 100 parts by mass were weighed. The weighed components were mixed for 24 hours in a bead mill using zirconia beads having a diameter of 0.5 mm to produce a black dispersion. The obtained black dispersion had a black particle amount of 20% by mass.

### Invention Examples 2 to 14 and Comparative Examples 1 to 3

Black dispersions of Invention Examples 2 to 14 and Comparative Examples 1 to 3 were produced in the same manner as in Invention Example 1, except that those shown in Table 1 which will be given later were used as the polymer dispersant and the solvent, and the blending amounts of the polymer dispersant and the solvent were changed such that the amount of the polymer dispersant with respect to the black pigment was the value shown in Table 1 which will be given later.

### [Evaluation]

A portion of the black dispersion immediately after production was taken out and diluted with benzyl methacrylate until the particle concentration was 1% by mass to prepare a diluted black dispersion. The average particle diameter (in terms of scattering intensity) of the black particles in the obtained diluted black dispersion was measured using a dynamic light scattering particle size distribution analyzer (Zetasizer Nano ZSP, manufactured by Spectris Co., Ltd.). The results are shown in Table 1 as the average particle diameter immediately after production.

In addition, the black dispersion was placed in a light-shielding glass bottle which was then sealed and allowed to stand in an environment at a temperature of 40° C. for 100 hours. At this time, a lid of the glass bottle was opened for 5 minutes every 12 hours. The black dispersion after storage was diluted in the same manner as that before storage to prepare a diluted black dispersion, and the average particle diameter of the black particles was measured. The results are shown in Table 1 as the average particle diameter after storage at 40° C. for 100 hours.

TABLE 1

| | Black dispersion | | | | | |
|---|---|---|---|---|---|---|
| | | Polymer dispersant | | | | |
| | | | Amount with | | Average particle diameter (nm) | |
| | Amount of | | respect to | | | After storage at |
| | black powder | | black powder | | Immediately | 40° C. for 100 |
| | (% by mass) | Type | (% by mass) | Solvent | after production | hours |
| Invention | 20 | Dispersant A | 20 | Benzyl acrylate | 120 | 121 |
| Example 1 | | | | | | |
| Invention | 20 | Dispersant B | 20 | Tetrahydrofurfuryl acrylate | 144 | 149 |
| Example 2 | | | | | | |
| Invention | 20 | Dispersant C | 20 | 2-Hydroxyethyl methacrylate | 138 | 145 |
| Example 3 | | | | | | |
| Invention | 10 | Dispersant A | 45 | 2-Ethylhexyl acrylate | 164 | 169 |
| Example 4 | | | | | | |
| Invention | 15 | Dispersant B | 30 | Benzyl methacrylate | 132 | 133 |
| Example 5 | | | | | | |
| Invention | 5 | Dispersant A | 35 | Lauryl acrylate | 172 | 177 |
| Example 6 | | | | | | |
| Invention | 35 | Dispersant A | 15 | Isobornyl acrylate | 164 | 167 |
| Example 7 | | | | | | |
| Invention | 10 | Dispersant A | 25 | Stearyl acrylate | 182 | 192 |
| Example 8 | | | | | | |
| Invention | 20 | Dispersant B | 15 | 1,6-Hexanediol diacrylate | 155 | 172 |
| Example 9 | | | | | | |
| Invention | 25 | Dispersant B | 10 | 1,9-Nonanediol diacrylate | 164 | 172 |
| Example 10 | | | | | | |
| Invention | 20 | Dispersant C | 20 | Polyethylene glycol 200 | 201 | 206 |
| Example 11 | | | | diacrylate | | |
| Invention | 5 | Dispersant A | 10 | Phenoxyethyl methacrylate | 162 | 182 |
| Example 12 | | | | | | |
| Invention | 20 | Dispersant C | 15 | Ethylene glycol | 221 | 244 |
| Example 13 | | | | dimethacrylate | | |
| Invention | 20 | Dispersant A | 5 | Isodecyl acrylate | 164 | 168 |
| Example 14 | | | | | | |
| Comparative | 20 | Dispersant D | 20 | Benzyl acrylate | 210 | Sedimented |
| Example 1 | | | | | | |
| Comparative | 20 | Dispersant E | 20 | Lauryl acrylate | 180 | Sedimented |
| Example 2 | | | | | | |
| Comparative | 20 | Dispersant F | 20 | 2-Hydroxyethyl methacrylate | 142 | 520 |
| Example 3 | | | | | | |

In the black dispersions of Invention Examples 1 to 14, the dispersants A to C were used as the polymer dispersants. In the dispersants A to C, the main chain was a polyalkyleneimine, and each of a plurality of side chains was a group containing an oxyethylene group and an oxypropylene group. From the results in Table 1, it was confirmed that, in the black dispersions of Invention Examples 1 to 14, the change in the average particle diameter of the black particles was small, and the black particles maintained a good dispersion state, even after being stored in an environment at 40° C. for 100 hours. On the other hand, the dispersants D to F were used in the black dispersions of Comparative Examples 1 to 3. These dispersants D to F had a phosphoric acid group or a carboxylic acid group as the adsorption functional group. For the black dispersions of Comparative Examples 1 to 3, after being allowed to stand in an environment at 40° C. for 100 hours, the dispersions became unstable, and the black particles in the dispersions sedimented or the average particle diameter of the black particles increased.

### Invention Example 15

The black dispersion obtained in Invention Example 1 was stored at 40° C. for 100 hours. 20 parts by mass of the black dispersion after being stored at 40° C. for 100 hours, 755 parts by mass of urethane acrylate (UF-07DF, manufactured by Kyoeisha Chemical Co., Ltd.) as the ultraviolet ray-curable organic substance, and 23 parts by mass of bis(2,4,6-trimethylbenzoyl)phenylphosphine oxide as the ultraviolet curing agent were weighed, and mixed and defoamed using a planetary stirrer (Awatori Rentaro, manufactured by Thinky Corporation) to produce an ultraviolet ray-curable black composition. In the obtained ultraviolet ray-curable black composition, the amount of the black pigment was 0.5% by mass, and the amount of the ultraviolet curing agent was 3.0 parts by mass with respect to 100 parts by mass of the ultraviolet ray-curable organic substance.

### Invention Examples 16 to 28 and Comparative Examples 4 to 6

Each of black dispersions obtained in Invention Examples shown in Table 2 which will be given later was stored at 40° C. for 100 hours. Ultraviolet ray-curable black compositions of Invention Examples 16 to 28 and Comparative Examples 4 to 6 were produced in the same manner as in Invention Example 15, except that the black dispersion after being stored at 40°° C. for 100 hours was used, those shown in Table 2 which will be given later were used as the ultraviolet ray-curable organic substance and the ultraviolet curing agent, and the blending amounts of the black dispersion, the ultraviolet ray-curable organic substance, and the ultraviolet curing agent were changed to the amounts shown in Table 2. The amounts of the black pigment in the ultraviolet ray-curable black compositions obtained in Invention Examples 15 to 28 were all 0.5% by mass.

### [Evaluation]

The obtained ultraviolet ray-curable black composition was charged into a mold with a diameter of 5 mm and a depth of 1 mm. Next, ultraviolet curing was carried out by irradiation with ultraviolet rays having an illuminance of 4000 mW/cm² and a wavelength of 365 nm for 3 minutes using a spot type UV-LED irradiator (8332C, manufactured by CCS Inc.). The obtained cured product was taken out from the mold to obtain a black resin composition.

The OD value of the obtained black resin composition was measured using a transmission densitometer (T5 plus, manufactured by Ihara Electronic Industries Co., Ltd.).

The results are shown in Table 2.

TABLE 2

| | Ultraviolet ray-curable black composition | | | | | | |
|---|---|---|---|---|---|---|---|
| | Black dispersion | | Ultraviolet ray-curable organic substance | | Ultraviolet curing agent | | |
| | | Formulation | | Formulation | | Formulation | Resin |
| | | amount | | amount | | amount | composition |
| | Designation | (parts by mass) | Designation | (parts by mass) | Designation | (parts by mass) | OD value |
| Invention | Invention | 20 | Urethane acrylate | 755 | Bis(2,4,6- | 23 | 3.4 |
| Example 15 | Example 1 | | UF-07DF (Kyoeisha | | trimethylbenzoyl)phenyl- | | |
| | | | Chemical Co., Ltd.) | | phosphine oxide | | |
| Invention | Invention | 20 | Epoxy acrylate | 755 | 2-Hydroxy-2-methyl- | 23 | 3.1 |
| Example 16 | Example 2 | | Epoxy ester 40EM | | propiophenone | | |
| | | | (Kyoeisha Chemical Co., | | | | |
| | | | Ltd.) | | | | |
| Invention | Invention | 20 | Urethane acrylate | 755 | 2,4,6-Trimethylbenzoyl- | 23 | 3.2 |
| Example 17 | Example 3 | | SHIKO UV2750B (Mitsubishi | | diphenylphosphine | | |
| | | | Chemical Corporation) | | oxide | | |
| Invention | Invention | 40 | Epoxy acrylate | 723 | 2-Hydroxy-2-methyl- | 35 | 3.2 |
| Example 18 | Example 4 | | Epoxy ester M-600A | | propiophenone | | |
| | | | (Kyoeisha Chemical Co., | | | | |
| | | | Ltd.) | | | | |
| Invention | Invention | 27 | Pentaerythritol | 741 | Bis(2,4,6- | 30 | 3.3 |
| Example 19 | Example 5 | | triacrylate | | trimethylbenzoyl)phenyl- | | |
| | | | | | phosphine oxide | | |
| Invention | Invention | 80 | Urethane acrylate | 683 | Bis(2,4,6- | 35 | 3.2 |
| Example 20 | Example 6 | | SHIKO UT5642 (Mitsubishi | | trimethylbenzoyl)phenyl- | | |
| | | | Chemical Corporation) | | phosphine oxide | | |
| Invention | Invention | 11 | Urethane acrylate | 775 | Bis(2,4,6- | 12 | 3.3 |
| Example 21 | Example 7 | | SHIKO UV2750B (Mitsubishi | | trimethylbenzoyl)phenyl- | | |
| | | | Chemical Corporation) | | phosphine oxide | | |
| Invention | Invention | 40 | Urethane acrylate | 726 | Bis(2,4,6- | 32 | 3.1 |
| Example 22 | Example 8 | | SHIKO UV2750B (Mitsubishi | | trimethylbenzoyl)phenyl- | | |
| | | | Chemical Corporation) | | phosphine oxide | | |
| Invention | Invention | 20 | Urethane acrylate | 755 | Bis(2,4,6- | 23 | 3.2 |
| Example 23 | Example 9 | | UF-07DF (Kyoeisha | | trimethylbenzoyl)phenyl- | | |
| | | | Chemical Co., Ltd.) | | phosphine oxide | | |
| Invention | Invention | 16 | Urethane acrylate | 762 | Bis(2,4,6- | 20 | 3.3 |
| Example 24 | Example 10 | | UF-07DF (Kyoeisha | | trimethylbenzoyl)phenyl- | | |
| | | | Chemical Co., Ltd.) | | phosphine oxide | | |
| Invention | Invention | 20 | Urethane acrylate | 755 | Bis(2,4,6- | 23 | 3.2 |
| Example 25 | Example 11 | | SHIKO UV2750B (Mitsubishi | | trimethylbenzoyl)phenyl- | | |
| | | | Chemical Corporation) | | phosphine oxide | | |
| Invention | Invention | 80 | Urethane acrylate | 698 | Bis(2,4,6- | 20 | 3.3 |
| Example 26 | Example 12 | | UF-07DF (Kyoeisha | | trimethylbenzoyl)phenyl- | | |
| | | | Chemical Co., Ltd.) | | phosphine oxide | | |
| Invention | Invention | 20 | Urethane acrylate | 763 | Bis(2,4,6- | 15 | 3.2 |
| Example 27 | Example 13 | | SHIKO UV2750B | | trimethylbenzoyl)phenyl- | | |
| | | | (Mitsubishi Chemical | | phosphine oxide | | |
| | | | Corporation) | | | | |
| Invention | Invention | 20 | Urethane acrylate | 768 | Bis(2,4,6- | 10 | 3.2 |
| Example 28 | Example 14 | | SHIKO UV2750B | | trimethylbenzoyl)phenyl- | | |
| | | | (Mitsubishi Chemical | | phosphine oxide | | |
| | | | Corporation) | | | | |
| Comparative | Comparative | 20 | Urethane acrylate | 755 | Bis(2,4,6- | 23 | 1.9 |
| Example 4 | Example 1 | | UF-07DF (Kyoeisha | | trimethylbenzoyl)phenyl- | | |
| | | | Chemical Co., Ltd.) | | phosphine oxide | | |
| Comparative | Comparative | 20 | Urethane acrylate | 755 | Bis(2,4,6- | 23 | 1.9 |
| Example 5 | Example 2 | | UF-07DF (Kyoeisha | | trimethylbenzoyl)phenyl- | | |
| | | | Chemical Co., Ltd.) | | phosphine oxide | | |
| Comparative | Comparative | 20 | Urethane acrylate | 755 | Bis(2,4,6- | 23 | 2.4 |
| Example 6 | Example 3 | | SHIKO UV2750B | | trimethylbenzoyl)phenyl- | | |
| | | | (Mitsubishi Chemical | | phosphine oxide | | |
| | | | Corporation) | | | | |

In the ultraviolet ray-curable black compositions of Invention Examples 15 to 28, the black dispersions of Invention Examples 1 to 14 after being stored at 40° C. for 100 hours were used. From the results in Table 2, it was confirmed that the black resin compositions obtained by curing the ultraviolet ray-curable black compositions of Invention Examples 15 to 28 all exhibited a high OD of 3 or more. On the other hand, in the ultraviolet ray-curable black compositions of Comparative Examples 4 to 6, the black dispersions of Comparative Examples 1 to 3 after being stored at 40° C. for 100 hours were used. The black resin compositions obtained by curing the ultraviolet ray-curable black compositions of Comparative Examples 4 to 6 all had a low OD of less than 2.5.

### INDUSTRIAL APPLICABILITY

In the black dispersion of the present embodiment, black particles do not easily agglomerate even in a case of being stored in the atmosphere for a long period of time, and the black particles are stably dispersed in a solvent. Therefore, an ultraviolet ray-curable black composition containing the black dispersion of the present embodiment can be used, for example, as a material for forming a black pattern such as a black resist or a black ink for inkjet. In addition, the resin composition of the present embodiment, which is a cured product of the ultraviolet ray-curable black composition, can be used as a black matrix of an image forming element used in displays such as liquid crystal displays and organic EL displays, or as a light shielding material in image sensors such as CMOS sensors. Furthermore, the resin composition of the present embodiment can also be used as a material for light shielding materials for optical members, light shielding filters, IR cut filters, and coverlay films.

1. A black dispersion comprising:
a solvent;
a black pigment; and
a polymer dispersant,
wherein the solvent contains either one or both of a monofunctional monomer having an ethylenically unsaturated bond and a difunctional monomer having an ethylenically unsaturated bond,
the black pigment contains zirconium nitride, and
the polymer dispersant contains a comb polymer, the comb polymer has a main chain and a plurality of side chains bonded to the main chain, the main chain is a polyalkyleneimine, and each of the plurality of side chains is a group containing an oxyethylene group and an oxypropylene group.

2. The black dispersion according to claim 1, wherein the comb polymer is a polymer represented by General Formula (I), 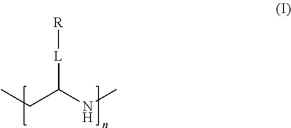
in General Formula (I), R represents a group containing an oxyethylene group and an oxypropylene group, L represents a single bond or a divalent linking group, and n represents a number of 5 to 30.

3. An ultraviolet ray-curable black composition comprising:
the black dispersion according to claim 1;
an ultraviolet ray-curable organic substance; and
an ultraviolet curing agent.

4. The ultraviolet ray-curable black composition according to claim 3, wherein the ultraviolet ray-curable organic substance is an oligomer having an ethylenically unsaturated bond or a polyfunctional monomer having three or more ethylenically unsaturated bonds.

5. The ultraviolet ray-curable black composition according to claim 3, wherein the ultraviolet ray-curable black composition is used for a black resist.

6. A resin composition that is a cured product of the ultraviolet ray-curable black composition according to claim 3.

7. A black matrix for color filters, comprising:
a cured product of the ultraviolet ray-curable black composition according to claim 3.

8. A CMOS camera module comprising:
a light shielding material containing a cured product of the ultraviolet ray-curable black composition according to claim 3.

9. An ultraviolet ray-curable black composition comprising:
the black dispersion according to claim 2;
an ultraviolet ray-curable organic substance; and
an ultraviolet curing agent.

10. The ultraviolet ray-curable black composition according to claim 9, wherein the ultraviolet ray-curable organic substance is an oligomer having an ethylenically unsaturated bond or a polyfunctional monomer having three or more ethylenically unsaturated bonds.

11. The ultraviolet ray-curable black composition according to claim 9, wherein the ultraviolet ray-curable black composition is used for a black resist.

12. A resin composition that is a cured product of the ultraviolet ray-curable black composition according to claim 9.

13. A black matrix for color filters, comprising:
a cured product of the ultraviolet ray-curable black composition according to claim 9.

14. A CMOS camera module comprising:
a light shielding material containing a cured product of the ultraviolet ray-curable black composition according to claim 9.
